(19) United States
(12) Patent Application Publication
(10) Pub. No.: US 2026/0309779 A1
(43) Pub. Date: Oct. 8, 2026

(54) ELECTRIC TESTING SYSTEMS

(71) Applicant: PRACTON POWER EQUIPMENT PTY LTD, Greenfields, Western Australia (AU)

(72) Inventors: Mark Jason MARTIN, Guildford (AU); Bradley Michael SLATER, Halls Head (AU)

(21) Appl. No.: 19/481,456

(22) PCT Filed: May 6, 2024
(86) PCT No.: PCT/AU2024/050442

§ 371 Date: Nov. 4, 2025

(30) Foreign Application Priority Data
May 4, 2023 (AU) 2023901349

(51) Int. Cl. G01R 31/327; G01R 1/02; G01R 1/04; G01R 1/20; H01H 83/04; H02J 13/12

(52) U.S. Cl. CPC G01R 31/3275; G01R 1/025; G01R 1/04; G01R 1/206; H02J 13/12; H01H 83/04

(57) ABSTRACT

A test system comprising a testing apparatus (and method for operation thereof) for testing at least at one relay (such as an earth leakage relay 23) of an electric circuit of a switchboard (11) connected to a mains power supply through a circuit breaker (36) for selectively delivery of a first electric current being the electric current product of the mains power supply to an end user power supply (32). The apparatus to be described hereinafter comprises a testing device being adapted to be operatively connected to the relay for tripping of the relay via a second current, wherein the second current is generated by a power supply other than the mains power supply.

### TECHNICAL FIELD

The present invention relates to system for testing electric equipment.

The invention has been devised particularly, although not necessarily solely, in relation to system for conducting earth leakage testing.

### BACKGROUND ART

The following discussion of the background art is intended to facilitate an understanding of the present invention only. The discussion is not an acknowledgement or admission that any of the material referred to is or was part of the common general knowledge as at the priority date of the application.

Electrical earth leakage is electric current flowing to ground via an intended path. The unintended earth leakage electric current may be due to defective electric equipment or damaged insulation of electric conductors. The earth leakage current poses a relatively high risk because, for example, a person may receive an electric shock by entering in contact with electric leakage current. Thus, it is essential to conduct periodical tests that permit early detection of any earth leakage electric current.

Currently the industry has standards; and legislation and regulations are in place for statutory electrical earth leakage tests to be completed within periodic time frames. However, conventional test equipment does not cover all installed equipment to meet all the regulatory requirements.

Nevertheless, a multitude of testing equipment are available that comply with governmental regulations. However, this testing equipment has its drawbacks. In particular, when the testing equipment is put in use, an operator needs to connect the test probes (of the testing equipment) directly to the live circuit that is being tested. To access the live circuit, the operator needs to remove, for example, safety covers for exposing electrically conductive live parts which then, will be operatively connected to the test probes by the operator. This particular action of exposing live electrical parts and for the operator entering in proximity to the live electrical parts is in contravention of governmental regulation such as the Code of Practice for Persons working on or near energised electrical installations 2017 making this practice unacceptable, as it exposes personnel directly to electrical hazards.

Typical risks to be considered during conducting this unacceptable action are:
electric shock, if contact is made with exposed energised parts or due to high or low voltage flash-over;
explosion (arc blast) or flashover, for example if a metal tool or fixture is dropped onto energised busbars causing a short circuit;
exposure to high-temperature parts causing burns to bare skin; and
electrical fires caused, for example, by allowing moisture or dust to enter electrical equipment.

It is against this background that the present invention has been developed.

### SUMMARY OF INVENTION

According to a first aspect of the invention there is provided a testing apparatus for testing at least at one relay of an electric circuit of a switchboard connected to a mains power supply through a circuit breaker for selectively delivery of a first electric current to an end user power supply, the apparatus comprising a testing device being adapted to be operatively connected to the relay for tripping of the relay via a second current, wherein the second current is generated by a power supply other than the mains power supply.

Preferably, the testing apparatus further comprises a power supply for generating the second current.

Preferably, the testing apparatus further comprises a current loop operatively connecting the testing apparatus to the relay for delivery of the second current to the relay for tripping thereof.

Preferably, the relay comprises an earth leakage relay adapted to sense imbalances of the first current delivered by the power mains supply.

Preferably, the current loop operatively engages the earth leakage relay for tripping of the earth leakage relay when the second current flows through the current loop.

Preferably, the earth leakage relay comprises a toroid for receiving the current loop for operatively engaging the earth leakage relay with the current loop for tripping of the earth leakage relay when the second current flows through the current loop.

Preferably, the testing apparatus further comprises a bypass circuit operatively connecting the relay with a shunt coil, the shunt coil being operatively connected to the circuit breaker for actuating the circuit breaker to an open condition when the relay has been tripped generating a tripping signal, the bypass circuit comprising a bypass switch for selectively impeding or allowing the tripping signal to actuate the circuit breaker to the open condition.

Preferably, the testing apparatus further comprises processing units configured for generating the second electric current to be delivered to the relay for testing purposes.

Preferably, the processing unit further comprising the input/output means for setting-up the testing process by an operator and for identification of the switchboard including the relay, and collection of information representative of the testing process and of the switchboard and relay.

Preferably, setting up the testing process comprises defining the second current, the trip time of the relay, and selectively turning the bypass option either on or off.

Preferably, the information representative of the testing process and of the switchboard and relay comprises trip time, location of the switchboard, type of relay and status, and voltage.

Preferably, the testing device comprises an interface module and a test unit operatively attached with respect to each other, the test unit generating the second current.

Preferably, the interface module is adapted to receive the second current for delivery to the current loop for tripping the relay.

Preferably, the interface module comprises the bypass switch.

Preferably, the interface module is installed within the switchboard.

Preferably, the interface module is incorporated in the test unit.

Preferably, the test unit is incorporated in the test unit.

Preferably, the test unit is adapted for setting up the testing process and obtaining information about the testing procedure and status of the electric circuit including the relay.

Preferably, information representative of the testing process and of the switchboard and relay comprises trip time, location of the switchboard, type of relay and status, and voltage.

Preferably, the test unit comprises a portable test unit for an operator to take to site for conducting the earth leakage testing while the operator is adjacent the switchboard.

Preferably, the test unit is adapted to be operated from a remote location such as a control room permitting setting up the testing procedure and obtaining, at the remote location, information about the testing procedure and status of the electric circuit of the switchboard including the relay, and information representative of the testing procedure and of the switchboard and relay comprising trip time, location of the switchboard, type of relay and status, and voltage.

Preferably, the testing apparatus further comprises a reset unit for resetting remotely the circuit breaker and/or the relay.

Preferably, the testing apparatus is adapted to be operatively connected to a high voltage mains power supply.

Preferably, the second current is a relatively low voltage electric current with respect to the first current supplied by the mains power supply.

Preferably, the relay comprises an earth leakage relay.

According to a second aspect of the invention there is provided a system for testing at least one relay of an electric circuit of a switchboard connected to a mains power supply through a circuit breaker for selectively delivery of a first electric current to an end user power supply, wherein each circuit breaker is connected to a mains power supply for selectively delivery of electric current to an end user power supply, the system comprising the electric circuit of the switchboard including the relay, and a testing apparatus in accordance with the first aspect of the invention.

Preferably, the relay comprises an earth leakage relay.

According to a third aspect of the invention there is provided a switchboard comprising a testing apparatus according in accordance with the first aspect of the invention.

According to a fourth aspect of the invention there is provided method for testing least at one relay of an electric circuit of a switchboard connected to a mains power supply generating a first electric current through a circuit breaker for selectively delivery of the first electric current to an end user power supply, the method comprises the steps of:
connecting an apparatus in accordance with the first aspect of the invention to the electric circuit such that testing device is operatively connected to the relay for tripping of the relay via the second current to be delivered to the relay;
generating the second current; and
forwarding the second current to the relay for tripping thereof.

Preferably, the method further comprises either locating the circuit breaker in open condition or keeping the circuit breaker in closed condition after tripping of the relay.

Preferably, the method further comprises setting up the current and trip time of the relay.

Preferably, the method further comprises collecting information about the testing procedure and status of the electric circuit of the switchboard including the relay, and information representative of the testing process and of the switchboard and relay comprising trip time, location of the switchboard, type of relay and status, and voltage.

### BRIEF DESCRIPTION OF THE DRAWINGS

Further features of the present invention are more fully described in the following description of several non-limiting embodiments thereof. This description is included solely for the purposes of exemplifying the present invention. It should not be understood as a restriction on the broad summary, disclosure or description of the invention as set out above. The description will be made with reference to the accompanying drawings in which:

FIG. 1 is a schematic view of a particular arrangement of an earth leakage test system in accordance with the first embodiment of the invention;

FIG. 1a is photographic image of a particular arrangement of an earth leakage relay on which the earth leakage testing will be conducted;

FIG. 2 is a schematic circuit diagram view of the earth leakage test system shown in FIG. 1;

FIG. 3 is a block diagram illustrating the injector and interface units of the earth leakage test system shown in FIG. 1;

FIGS. 4 and 5 is a flowchart illustrating the electric testing process of the earth leakage test system shown in FIG. 1;

FIGS. 6 and 7 are schematic views of particular arrangements of earth leakage test systems in accordance with the second embodiment of the invention;

FIGS. 8 and 9 are schematic views of particular arrangements of earth leakage test systems in accordance with the third embodiment of the invention;

FIG. 10 is a schematic circuit diagram view of the earth leakage test system shown in FIG. 9;

FIG. 11 is a block diagram illustrating the integrated injector and interface unit of the earth leakage test system shown in FIG. 9;

FIGS. 12 and 13 is a flowchart illustrating the electric testing process of the earth leakage test system shown in FIG. 9;

FIGS. 14a to 14j are electric circuit diagrams of the portable units 16 and the interface unit 14 in accordance with the first embodiment of the invention; and

FIGS. 15a to 15k are electric circuit diagrams of the remote test unit 27 in accordance with the third embodiment of the invention.

### DESCRIPTION OF EMBODIMENT(S)

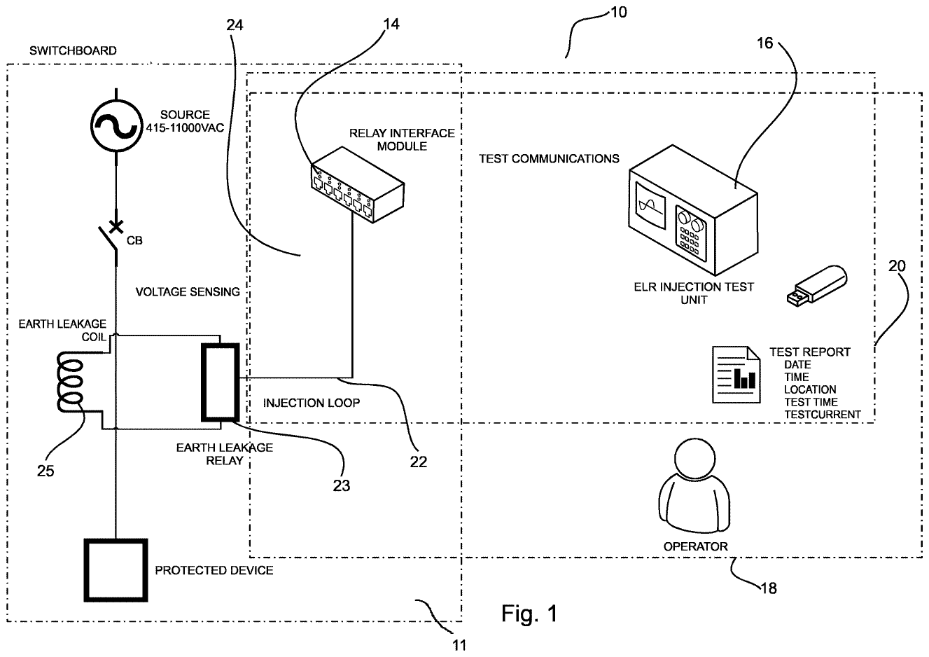

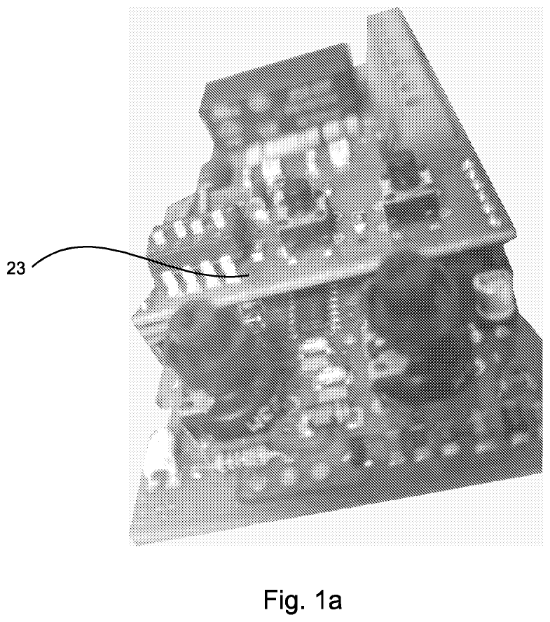

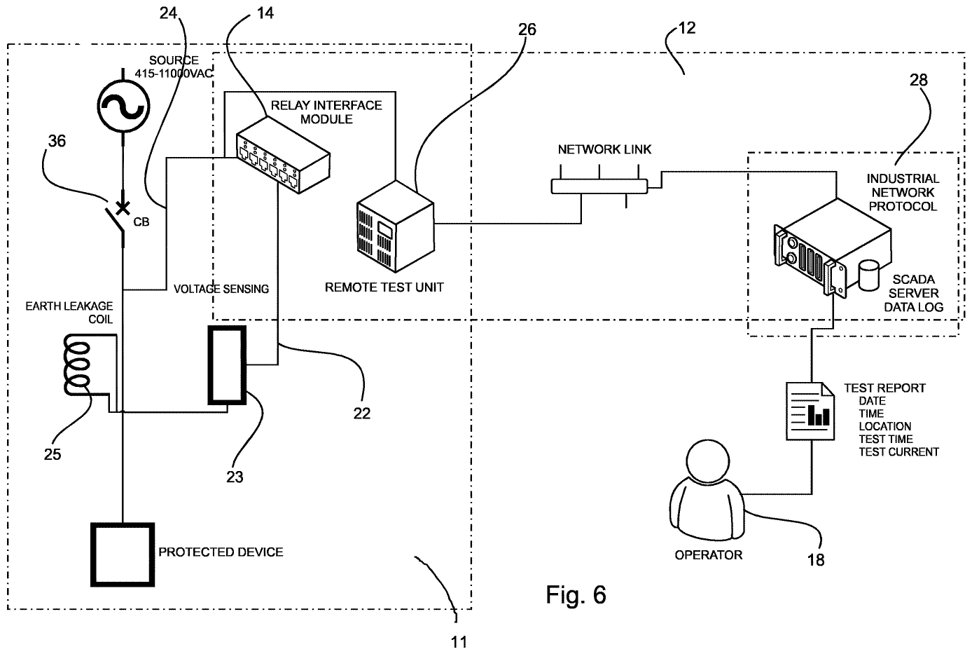

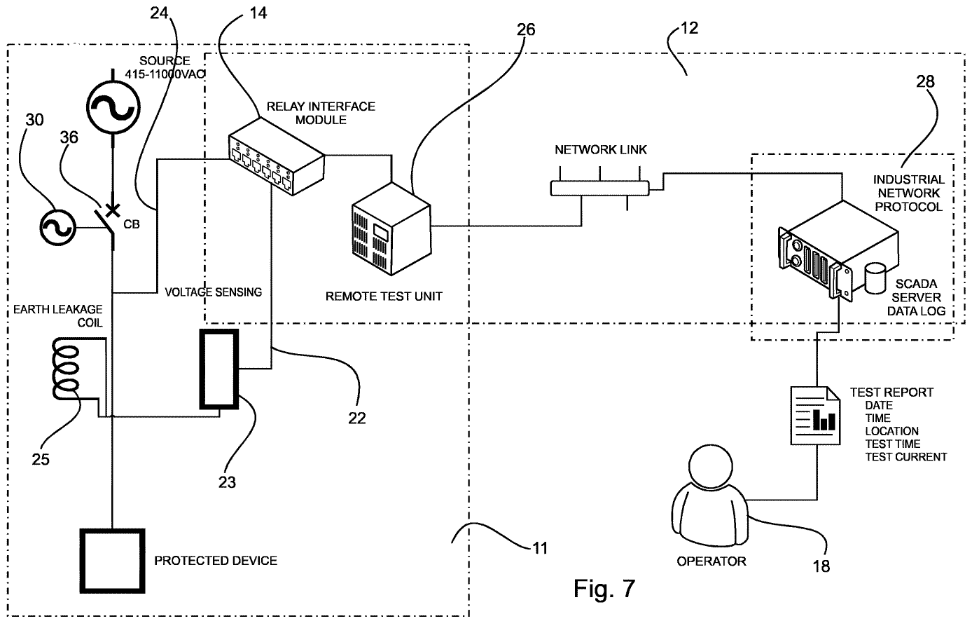

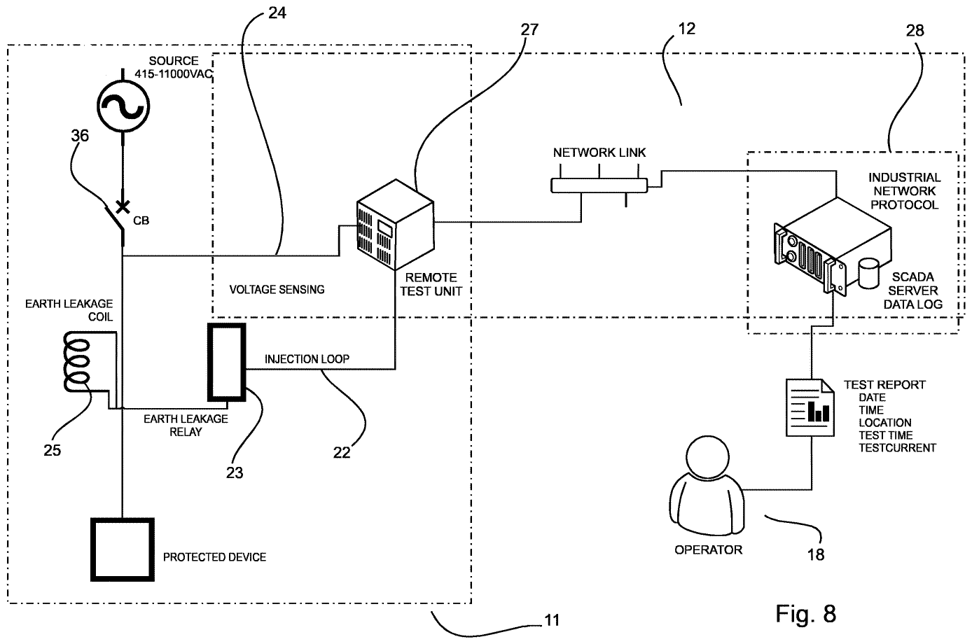

FIGS. 1 and 2, and 6 to 9 show particular arrangements of earth leakage test systems 10 and 12 in accordance with several embodiments of the invention. In particular, FIG. 1 shows a portable earth leakage test system 10 in accordance with a first embodiment of the invention; FIGS. 6 and 7 shows a remote earth leakage test system 12 in accordance with a second embodiment of the invention; and FIG. 8 and show a remote earth leakage test system 12 in accordance with a third embodiment of the invention.

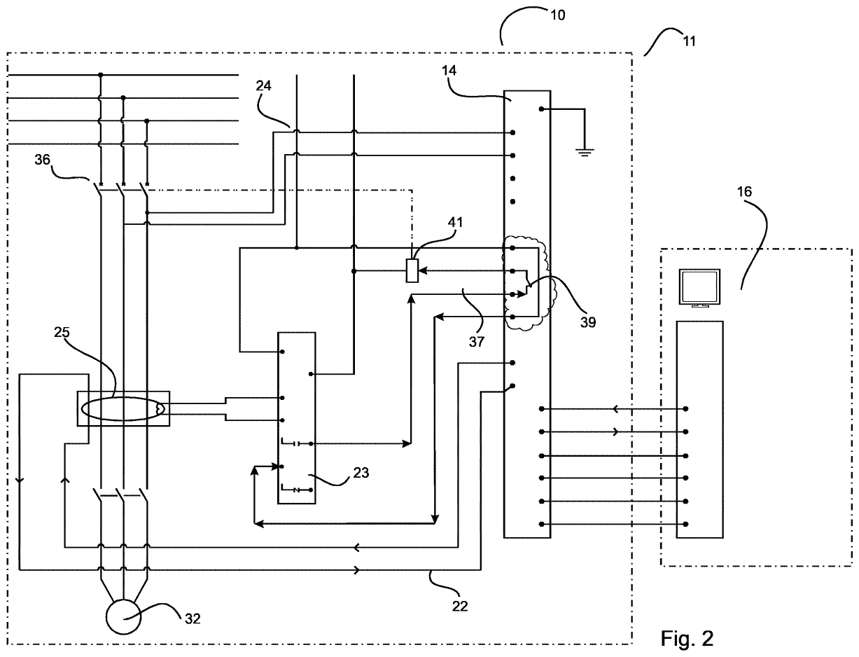

The test system comprise a testing apparatus for testing at least at one relay (such as an earth leakage relay 23 shown in FIG. 1a comprising a processor unit) of an electric circuit of a switchboard 11 connected to a mains power supply through a circuit breaker for selectively delivery of a first electric current being the electric current product of the mains power supply when to an end user power supply 32. The apparatus to be described hereinafter comprises a testing (the interface module 24 and the test units 16, 26 and 27) device being adapted to be operatively connected to the relay 23 for tripping of the relay 23 via a second current, wherein the second current is generated by a power supply other than the mains power supply. The relay 23 is adapted to communicate with testing apparatus as shown, in FIG. 2, through a bypass circuit 37.

The method of operation of the comprises the steps of: (a) connecting the apparatus to the electric circuit of the switchboard 11 such that testing device is operatively connected to the relay for tripping of the relay via a second current delivered to the relay, wherein the second current is generated by a power supply other than the mains power supply; (b) is engaged with the relay for sensing imbalances in the first current; and generating a second current wherein the second current is generated by a power supply other than the mains power supply.

The earth leakage test systems 10 and 12 are adapted to be operatively connected to an electric circuit comprising one or more earth leakage relays 23 included in a switchboard 11. Once the earth leakage test systems 10 and 12 are operatively connected to the switchboard 11, it is possible for operators to conduct tests to the earth leakage systems 10 and 12 to confirm whether the earth leakage relay 23 is operational. The operators may conduct the tests either on site (where the switchboard 11 is located) via the portable earth leakage test systems 10, or from a remote location via the remote earth leakage test systems 12. The earth leakage test systems 10 and 12 are also configured for generating and storing data representative of the earth leakage testing resulting in information for confirming correct operation of the testing process and of the earth leakage relay 23, as well as for issuing reports and future reference.

The earth leakage test systems 10 and 12 are particularly advantageous because they isolate operators from the particular electric circuit (including one or more earth leakage relays 23) to be tested by establishing a barrier between the electric circuit and the operators through which the operators may conduct the earth leakage testing.

In the particular arrangements shown in the figures, the barrier is formed by an interface module 14 adapted to be operatively connected to injection modules (16, 26 and 27) permitting the delivery, for example, to an earth leakage relay 23 of signals carrying a signal current (the second current) for the earth leakage testing to occur. The interface module 14 also allows delivery of information related to the testing procedure and status of the electric circuit including the earth leakage relay 23.

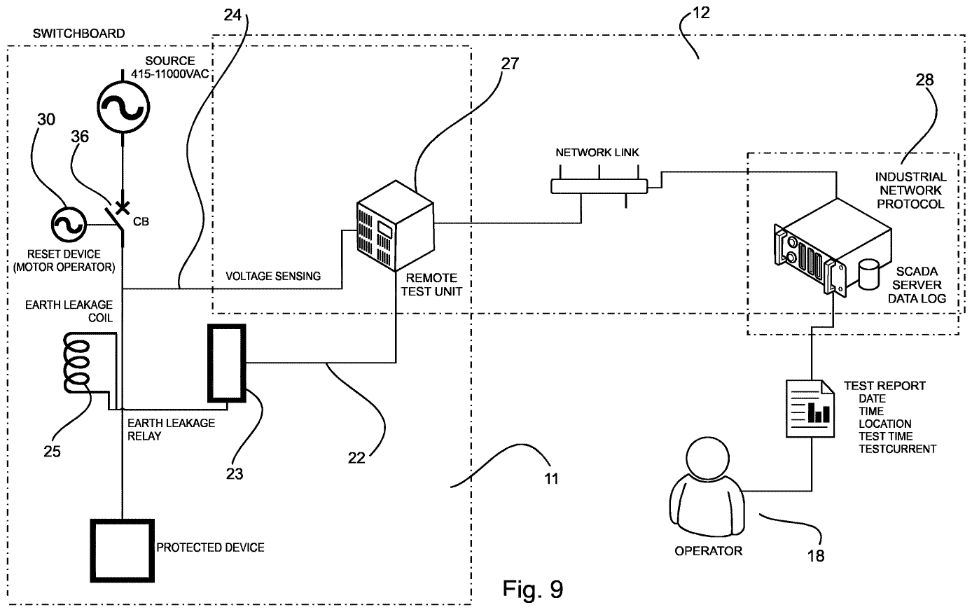

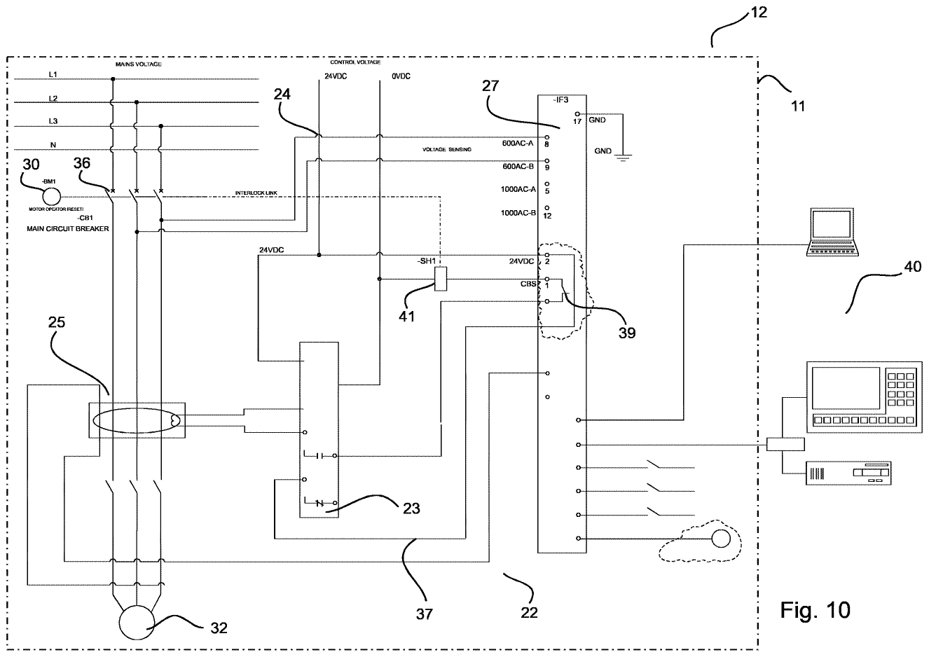

The injection modules (16, 26 and 27)—also referred to as test units—may be either (1) portable units (such the portable earth leakage test unit 16) that the operator may take to site for conducting the earth leakage testing while the operator is adjacent the closed switchboard 11, or (2) remote test units 26 and 27 incorporated into the switchboards 11. In a particular arrangement shown in FIGS. 9 and 10, the interface module 14 and the injection module 26 may be a single unit defining the remote earth leakage test unit 27 (referred to as the remote test unit 27) incorporating the interface module 14.

The remote test units 26 and 27 are adapted to be operated from a remote location such as a control room permitting conducting a multitude of earth leakage test to a multitude of switchboards 11 and obtaining at the remote location information about the testing procedure and status of the electric circuit including the earth leakage relay 23 and its location.

Referring now to FIG. 2, FIG. 2 shows earth leakage test systems 10 which comprises the portable test unit 16 operatively attached to the interface module 14. As shown in FIG. 2, the portable test unit 16 is adapted to be operatively connected to the switchboard 11 for delivering of current signals to the earth leakage relay 13 for testing thereof, and for receiving signals carrying the information related to the testing process and the electric system located within the switchboard.

The portable earth leakage test system 10 allows operators to conduct in a safe manner the earth leakage testing at site via the portable test unit 16 (also referred to as the injection module 16) adapted to be operatively connected to interface module 14 for conducting the earth leakage test.

As shown in FIG. 2, the portable earth leakage test system 10 comprises a relay interface module 14 (referred to as the interface module 14), and an injection test unit 16. In accordance with the first embodiment of the invention, the test unit 16 is portable (referred to as the portable test unit 16) defining the injection module mentioned earlier. The portable test unit 16 is adapted to generate the current signal that will trip the earth leakage relay 23 during the electric earth leakage test. The current signal is delivered through the interface module 14 to the earth leakage relay 23.

In particular, in the electric circuit of the switchboard 11 there is provided an injection loop 22 defining a conductive path for delivering the current signal to the earth leakage relay 23 in order to generate an imbalance in the total electric current (monitored by the earth leakage relay 23) passing through the three phases. The generation of the imbalance will be sensed by a toroid 25 of the earth leakage relay 23 resulting in the tripping of the earth leakage relay 23.

As shown in FIG. 2, a section of the injection loop 22 passes through the toroid 25 so that tripping of the earth leakage relay 23 is triggered when the operator actuates the portable test unit 16 generating the flow of the current signal in the current loop 22. The fact that the earth leakage relay 23 may be triggered by a signal current generated by a power source other than the mains power supply is particularly advantageous because it is possible to shield the operator from the mains power supply.

In accordance with the present embodiments of the invention, the signal current is of relatively low voltage with respect to mains power supply, thus keeping the operators safe when conducting the test and avoiding damage to the electric circuit of the switchboard 11 in case high voltage mains are connected to the switchboard 11. Another advantage that the signal current is obtained from a power supply other than the mains power supply, is the fact that the portable test unit 16 as well as the remote test units 26 and 27 (to be described in greater detail hereinafter) may be used for testing switchboards electrically connected to high voltage mains power supply having voltages greater than 1000 VAC.

Further, the portable test unit 16 is also configured for controlling and measuring the electric current (downstream the circuit breaker 36 operatively connected to the mains power supply) as well as the time it takes to trip the earth leakage relay 23 during an electrical earth leakage test. For this, as shown in FIG. 2, the interface module 14 is electrically connected to a voltage sensing circuit 24 and to the earth leakage relay 23 permitting delivery to the portable test unit 16 of electric signals carrying the information related to the current downstream the electric breaker 36, status of the earth leakage relay 23 and trip time of it, among others.

This information (for example, electric current measurements and trip relay time) together with the site information (for example, location and type of the particular electric circuit of a particular switchboard 11 undergoing testing) may be stored in the portable test unit 16 for provision to operators 18 for future reference. For example, as shown in FIG. 1, the information may be downloaded to a USB via a USB port operatively connected to a control system of the portable test unit 16, in particular to the memory of the portable test unit 16.

For installation of the portable test unit 16 to conduct the earth leakage test, the interface module 14 is installed within the switchboard 11, via DIN Rail mountable modules with a socket for an interface cable and screw terminals for voltage sense inputs and current loop connections, to an external control plug for test connection. The portable test unit 16 will be connected to the switchboard 11 under test cable via a Mil-Spec style bulkhead connector. This will ensure the operator is not exposed to any electrical live conductive part of the switchboard 11 in view that the door to the switchboard would remain closed. In this manner the barrier is defined shielding the operators from electric shock.

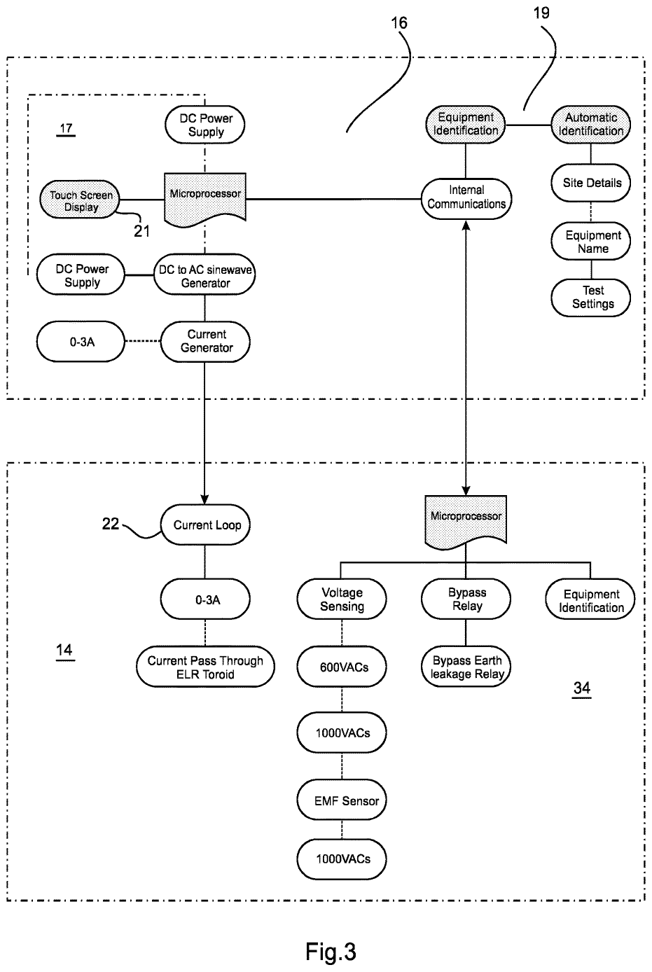

FIG. 3 shows a schematic representation of the portable test unit 16 and the interface module 14 in the form of a block diagrams.

As shown in FIG. 3, the portable test unit 16 comprises a first processing unit 17 and an identification unit 19.

The processing unit 17 is configured for generating an electric current of relatively low voltage defining the signal current to be delivered to the toroid 25 of the earth leakage relay 23 for testing purposes. There is provided a DC power supply and a DC to AC (e.g. sinewave) convertor generator of current operatively connected to the current loop 22 via the interface module 14 for testing of the earth leakage relay 23.

The processing unit 17 also comprises the input/output means to permit the operator to communicate with the portable test unit 16 and view and download the information collected during the testing process. In the arrangement shown, the input/output means comprises a touch screen display 21.

The identification unit 19 permits communication with the interface module 14 for delivery of the operator's instructions and receiving of the information related to the testing process, the electric current downstream the circuit breaker and upstream the earth leakage relay 23, status of earth leakage relay 23 and trip time, among others. The identification unit 19 is also adapted, during an equipment identification process, to obtain the information such as location of the site and type of switchboard and its electric circuit including the earth leakage relay 23.

In a particular arrangement, it is possible to set the earth leakage test system 10 in bypass mode. When the earth leakage test system 10 is set to be in the bypass mode, the mains power supply is not switched off permitting still, even though the earth leakage relay 23 has tripped, delivery of electric power to the end user power supply 32 (see FIG. 2).

As shown in FIG. 2, the interface unit 14 comprises a bypass circuit 37 comprising a switch 39 (the bypass switch) included in the interface unit 14. The bypass circuit 37 is illustrated via a sequence of arrows electrically connecting the earth leakage relay 23 with the interface unit 14 and the shunt coil 41, which is electrically connected to the circuit breaker 36 for tripping of the circuit breaker 36 when receiving a tripping signal from the earth leakage relay 23. In accordance with the present embodiments of the invention, the tripping signal is delivered to the bypass switch 39 incorporated in the interface unit 14, which the bypass switch 39-when in open condition as shown in FIG. 2-w ill impeded from reaching the circuit breaker 36 impeding triggering of the circuit breaker 36-when in closed condition, the bypass switch 39 will allow delivery of the tripping signal to the circuit breaker 36 tripping the circuit breaker 36.

Referring now to the interface module 14 shown in FIG. 3, there is provided the current loop 22 operatively connected to the processing unit 17 of the portable test unit 16 for receiving the current signal that will trip the earth leakage relay 23.

Also, the interface module 14 comprises a second processing unit 34 for governing the equipment identification and set-up processes to set up the trip time, set the value of signal current and turning the bypass mode either on or off. Also, the information collection process collects information such as voltage sensing and any other information related to the testing process and the status of the electric circuit including the earth leakage relay 23.

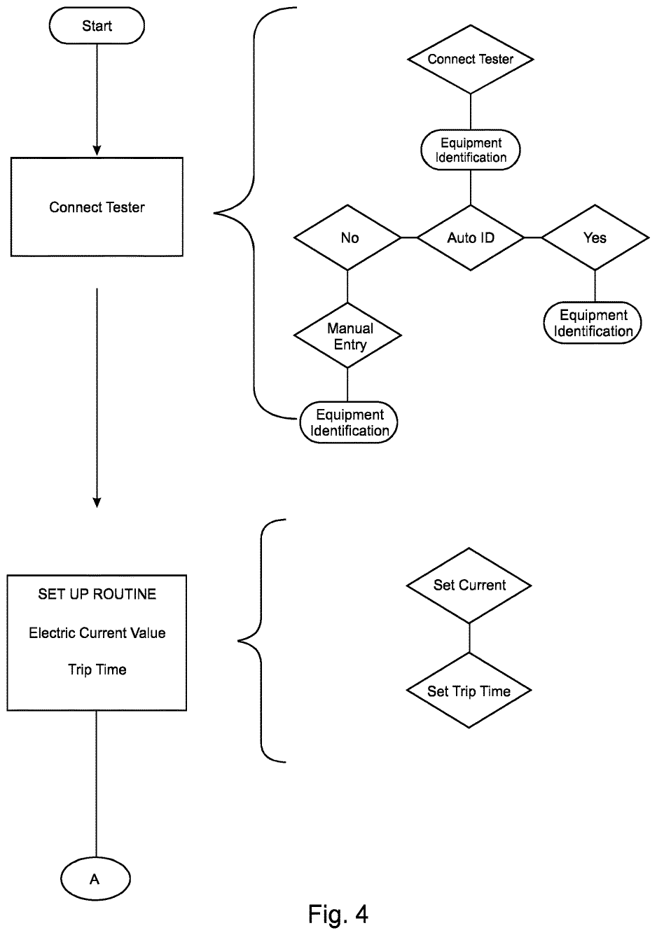

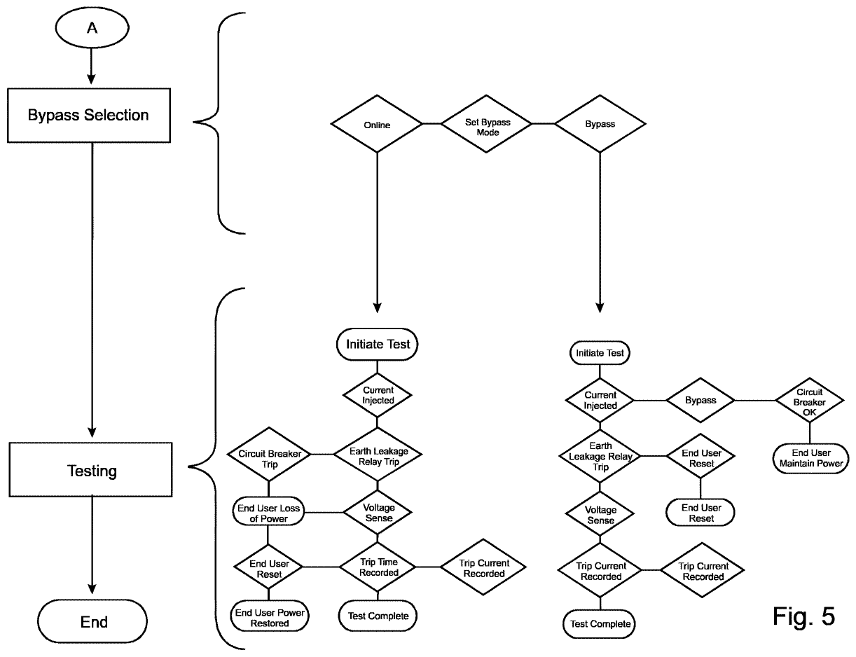

FIGS. 4 and 5 illustrates the process for conducting the earth leakage test. The process comprises a first step of operatively connecting the portable test unit 16 to the electric circuit of the switchboard 11 via the interface module 14. There may a manual identification of the equipment (i.e., the electric circuit comprising the earth leakage relay 23 and the switchboard 11) or an automatic identification. Identification includes collection of information related to location of the switchboard 11, type of earth leakage relay 23, among others.

Subsequently, there is a set up routine for, for example, the operator through the input/output means-to set up the value of the current signal to travel through the current loop 22 and the trip time, as well as the option is given to the operator to turn the bypass option on, or off referred to as the online option resulting in that the end power supply 32 is cut off.

At this stage, as shown in FIG. 5, the testing process may start with the current signal injected into the interface unit 14 for delivery to the current loop 22 resulting in tripping of the earth leakage relay 23. Depending on whether the bypass option was selected, the end user power supply 32 may still keep receiving electric power from the mains power supply.

The bypass option is particularly advantageous because it permits doing tests to the switchboard 11 which will not interrupt the normal operation of, for example, a mining operation dependent on electric power. In this manner, testing of the switchboards may be done more often due the fact that no disruption will occur. However, testing occurring with the bypass mode turned off may still be done but at greater spaced intervals. This reduces the overall disruptions, thus operational costs.

The information representative of the test will be collected and delivered to the portable test unit 16 for review by the operators on site, and storage for generation reports and future reference. This will have completed the testing process.

Referring now to FIGS. 6 to 9, FIGS. 6 to 9 show remote earth leakage test systems 12 in accordance with the second and third embodiments of the invention.

As shown in FIGS. 6 to 9, the remote earth leakage test systems 12 in accordance with the second and third embodiments of the invention comprises the relay interface module 14 (defining the interface module) and a remote ELR Injector Test Unit 26 (referred to as remote test unit 26) defining the injection module.

In this particular arrangement of the second embodiment shown in FIGS. 6 and 7, the remote test unit 26 is installed into the switchboard and operatively connected to the interface module 14. The remote test unit 26 is adapted to be operatively connected to the interface module 14 for generating the signal current that will trip the earth leakage relay 23 during an electrical earth leakage test.

In the arrangement of the third embodiment of the invention shown in FIGS. 8 and 9, the interface module 14 is incorporated into the remote test unit 26 defining the remote test unit 27 shown in FIGS. 8 and 9.

In the particular arrangements of the second and third embodiments of the invention, remote test units 26 and 27 are operatively connected via an industrial ethernet network reporting to an industrial control system 28 from which the remote test unit 26 is operated and controlled from a control room by operators.

The remote test units 26 and 27 are also configured for controlling and measuring the electric current as well as the time it takes to trip the relay during an electrical earth leakage test. This information is accessible via the industrial control network utilising common industrial protocols (Modbus TCP, Ethernet IP etc.).

The collected information (electric current measurements and trip relay time) together with the site information (for example, location and type of the particular electric circuit under evaluation) may be stored by the control system 28 for provision to operators 18. For example, as shown in FIG. 2, the information may be provided in the form of reports for perusal of the operators 18.

Referring now to FIGS. 7 and 9, the remote earth leakage test system 12 shown in these figures is substantially identical to the remote earth leakage test system 12 shown in FIGS. 6 and 8, except in that the remote earth leakage test system 12 shown in FIGS. 7 and 9 comprises a rest unit 30.

In accordance with a particular arrangement, the reset unit 30 is a servo drive operator specific to each type of switchgears present in the switchboards 11. The reset unit 30 comprises mechanisms to reset the corresponding circuit breaker 36 remotely after a test signal has been initiated and tripping of the circuit breaker 36 (if the bypass mode has been turned off) and the earth leakage relay 23 has occurred. Similarly, a reset unit is provided for remotely resetting the tripped the earth leakage relay 23.

Referring now to FIG. 10, FIG. 10 is a schematic circuit diagram of the leakage test systems 12 in accordance with the third embodiment showing in greater detail the electric circuit of the switchboard 11 including the earth leakage relay 23.

The descriptions related to the leakage test system 10 depicted in the schematic circuit diagram of FIG. 2, apply to FIG. 10 in relation to the testing process and the process for turning the bypass option either on or off. However, FIG. 10 shows the earth leakage test systems 12 including the remote test unit 27, which comprises a remote test unit substantially identical to the remote test units 26 shown in FIGS. 6 and 7 but incorporating the interface unit 14.

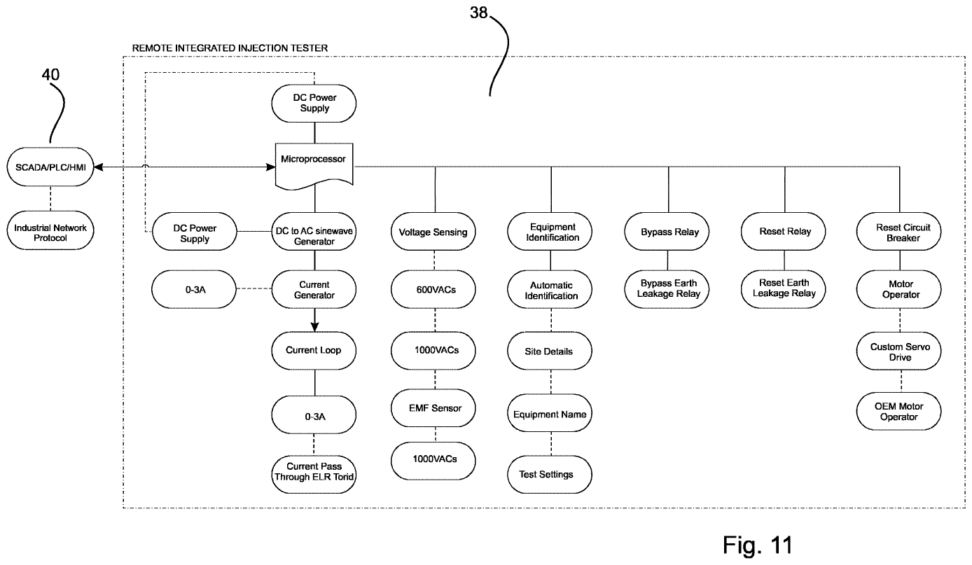

FIG. 11 shows a schematic representation of the remote test unit 27 (incorporating the interface module 14) in the form of a block diagrams.

As shown in FIG. 11, the portable test unit 16 comprises a processing unit 38 adapted to be operatively connected via an industrial ethernet network reporting to an industrial control system 40 from which the remote test unit 27 is operated controlled from a control room by operators. The processing unit 38 is configured for conducting the same tasks the first and second processing units 17, 19 and 34 of the portable test unit 16.

As shown in FIG. 11, the processing unit 40 also incorporates systems for remotely resetting the earth leakage relay, and the circuit breaker in case the bypass mode was turned off during testing.

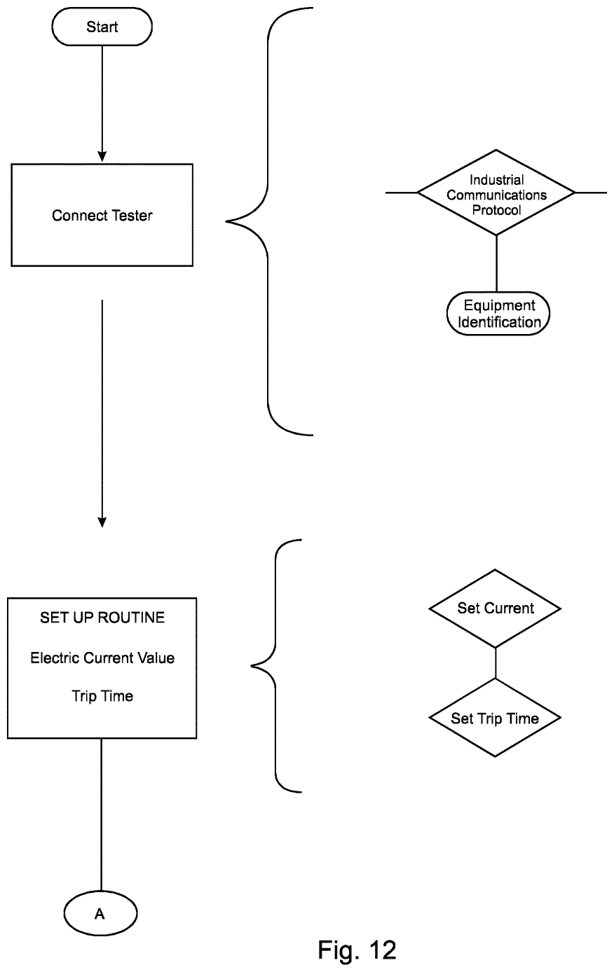

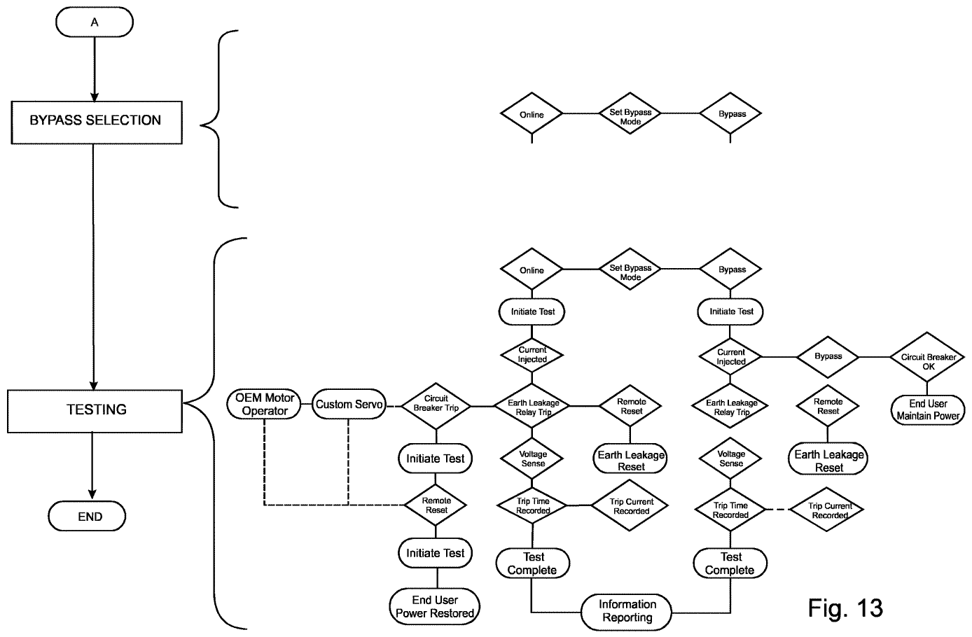

Referring now to FIGS. 12 and 13, FIGS. 12 and 13 illustrate the process for conducting the earth leakage test using the remote test units 26 and 27. The process comprises a first step of operatively connecting the portable test unit 16 to the electric circuit of the switchboard 11 via the interface module 14.

The testing process conducted by the remote test systems 12 is substantially identical to the process discussed in connection with the portable test system 10 illustrated in FIGS. 4 and 5 except that all processes are now controlled remotely from the industrial control system 40 including resetting of the earth leakage relay 23 and the circuit breaker 36. Also, any equipment identification is an automatic identification remotely triggered by operators of the industrial control system 40.

For installation of the remote test unit 26 to conduct the earth leakage test, the interface module 14 will be installed at each protection device switchboard, via DIN Rail mountable module with a socket for an interface cable and screw terminals for voltage sense inputs and current loop connections, connected to the remote test unit 26. As mentioned before, in a particular arrangement, the remote test unit 26 and interface module 24 may be integrated into a single unit defining the remote test unit 27.

The remote test units 26 and 27 will be installed at each protection device switchboard, via DIN Rail mountable module with either integrated interface unit or connected to the interface unit via communications cabling. The remote test unit 26 will be connected to the industrial control network via ethernet connection for operation of the remote test unit 26 reporting to the control system 28 for monitoring and control. This does not apply to the remote test unit 27 in view that the interface module 14 has been incorporated in the remote test unit 26.

The remote test unit 26 or 27 will be connected to the switchboard 11 under test cable via industrial control network via ethernet connection. This will ensure the operator is not exposed to any electrical live conductive part of the switchboard 11. The remote test units 26 and 27 will reduce operator test times providing significant savings. The test can be initiated remotely, and records accessed immediately. This providing secure and accurate data, thus ensuring all statutory records are maintained.

The remote reset option will significantly reduce overall test times and downtime while testing is completed. This will minimise production downtime and disruption, adding to the value and safety of the system.

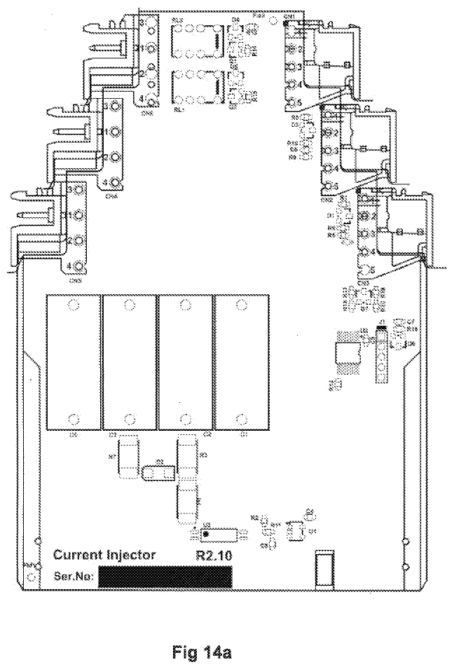

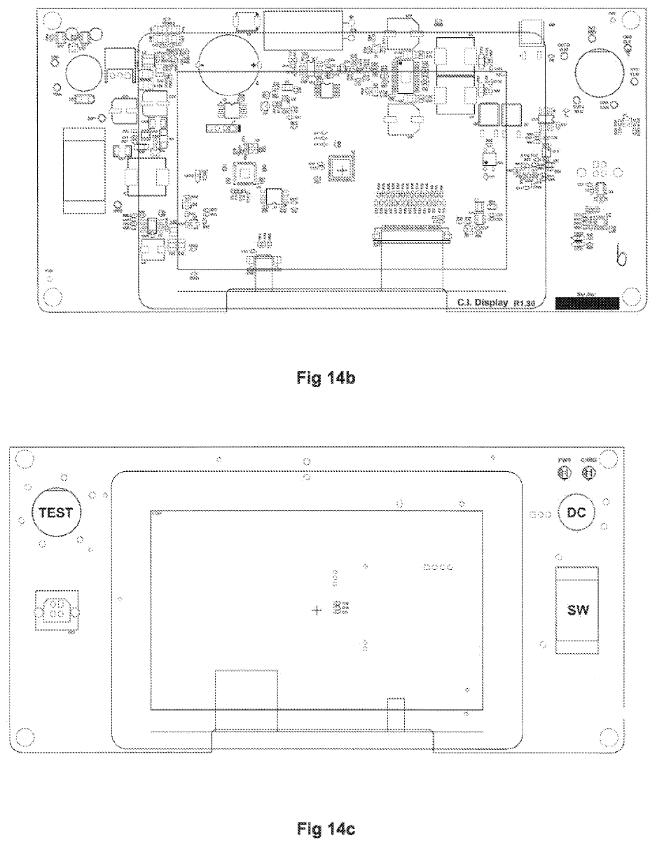

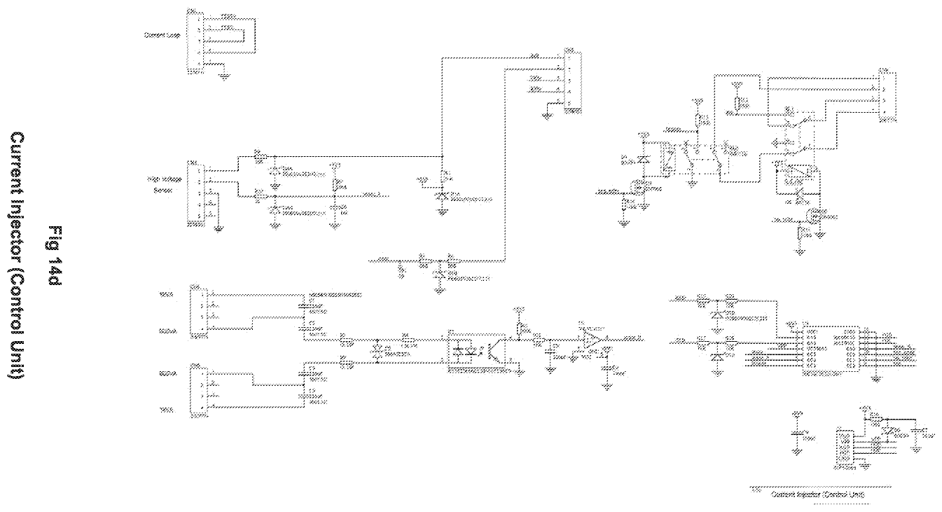

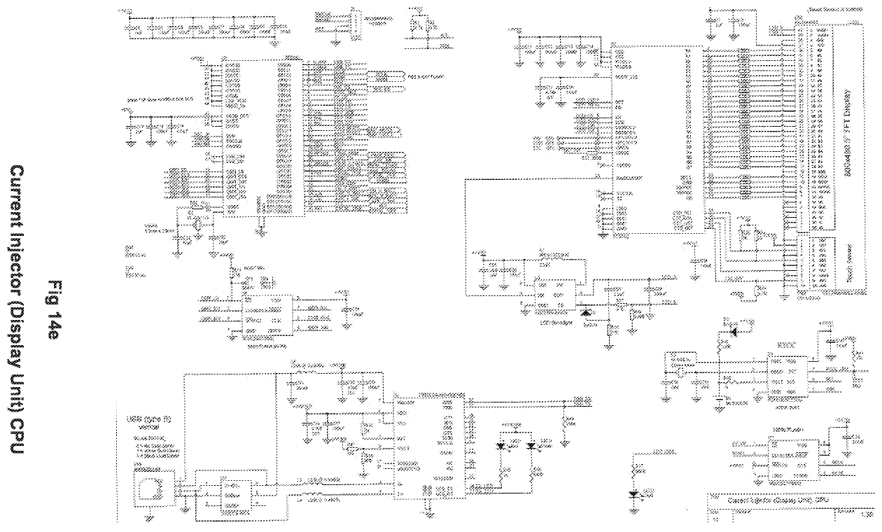

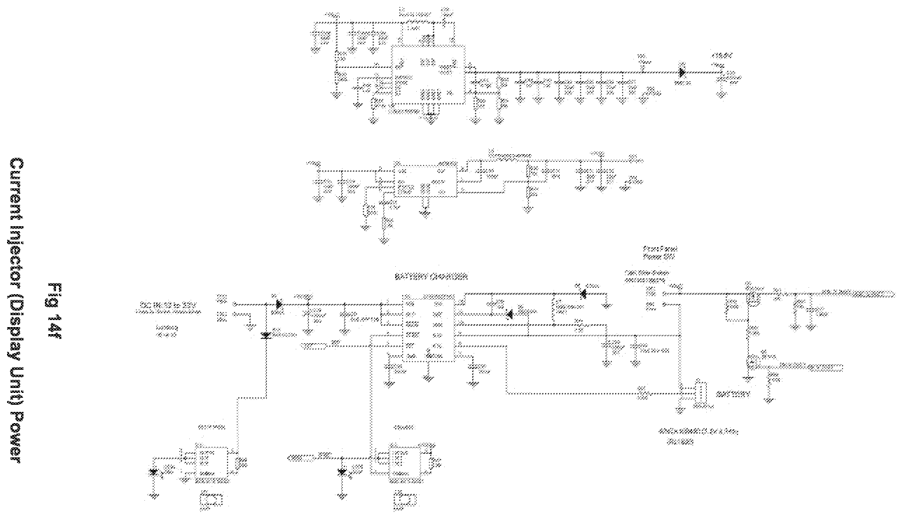

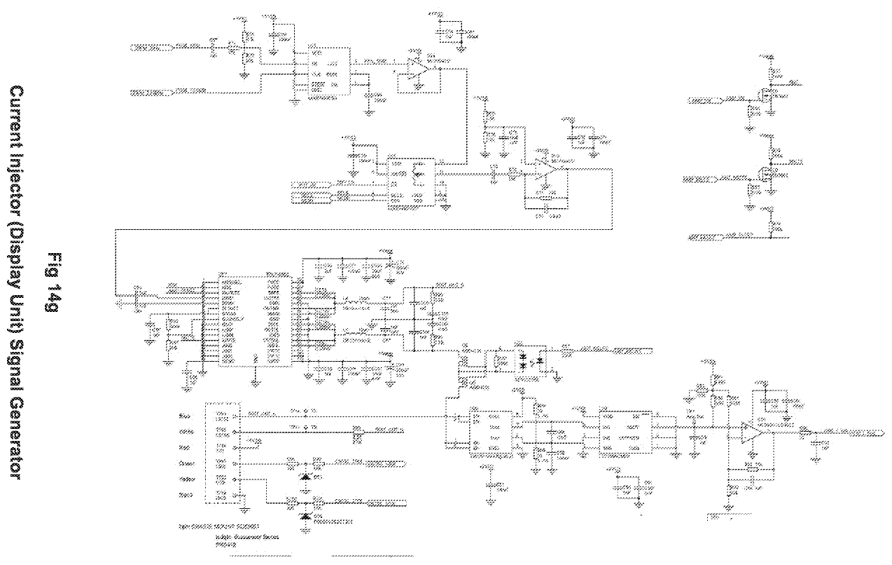

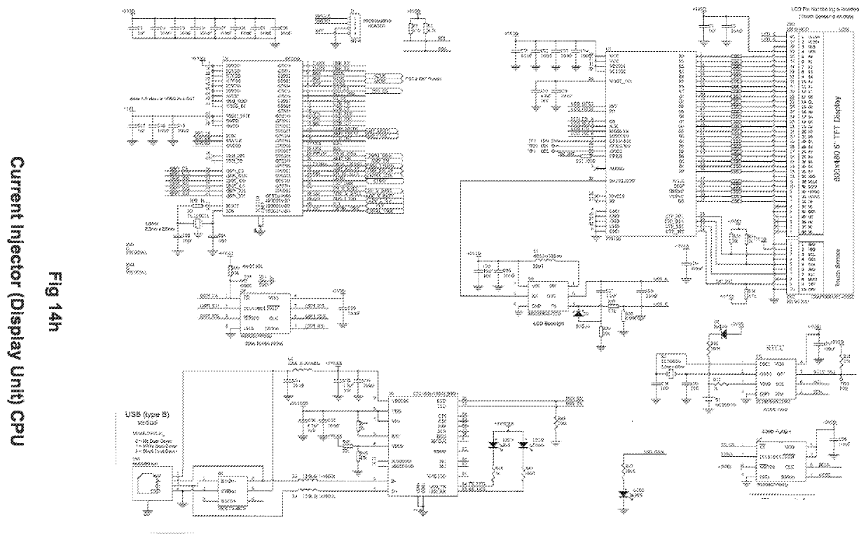

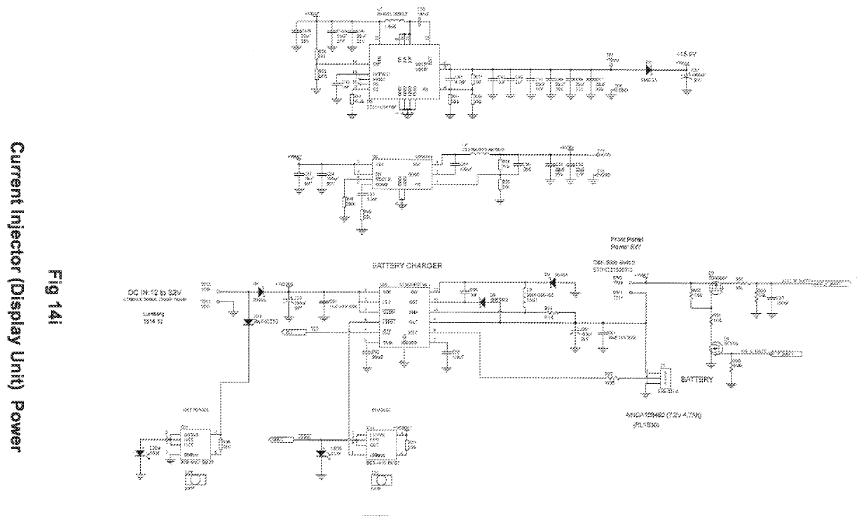

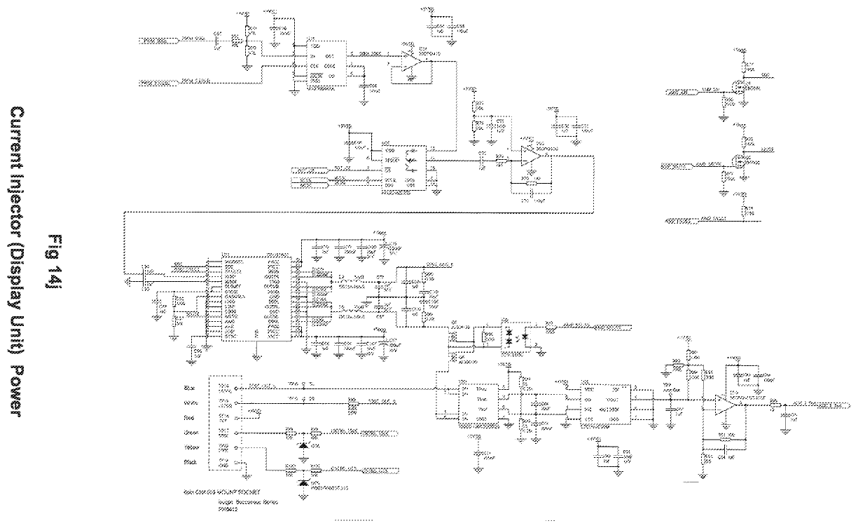

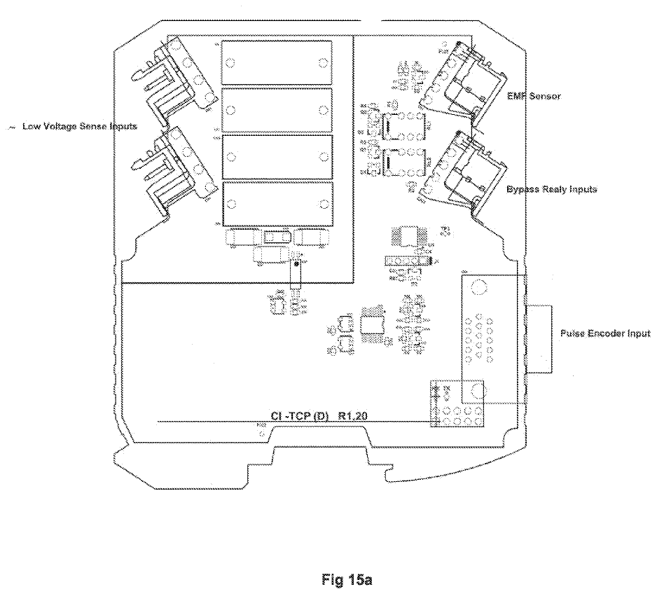

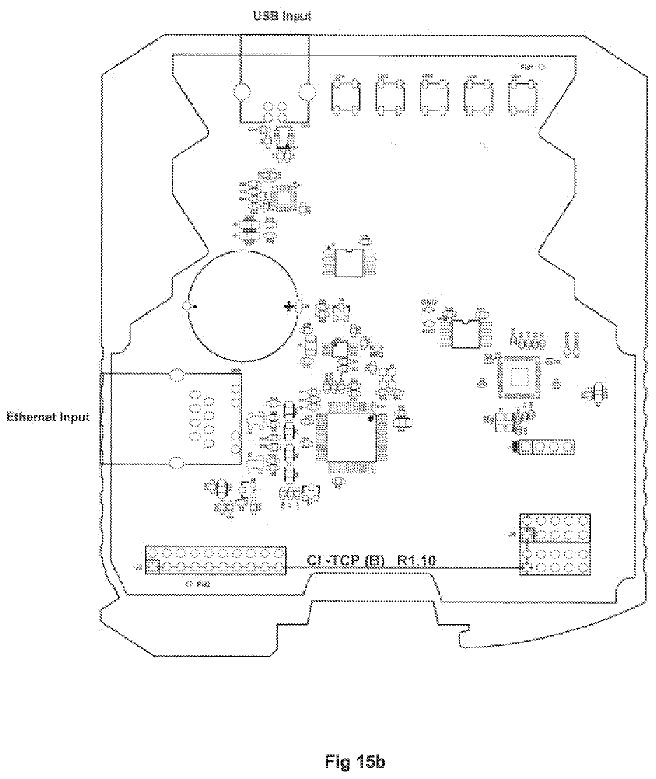

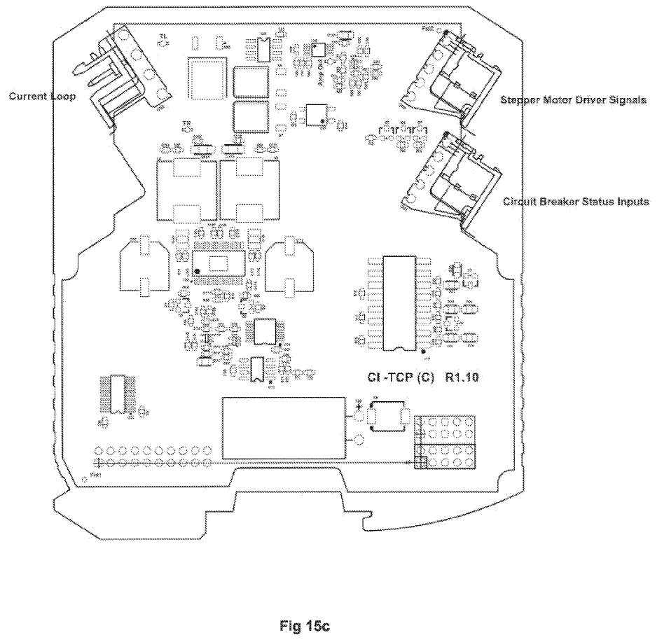

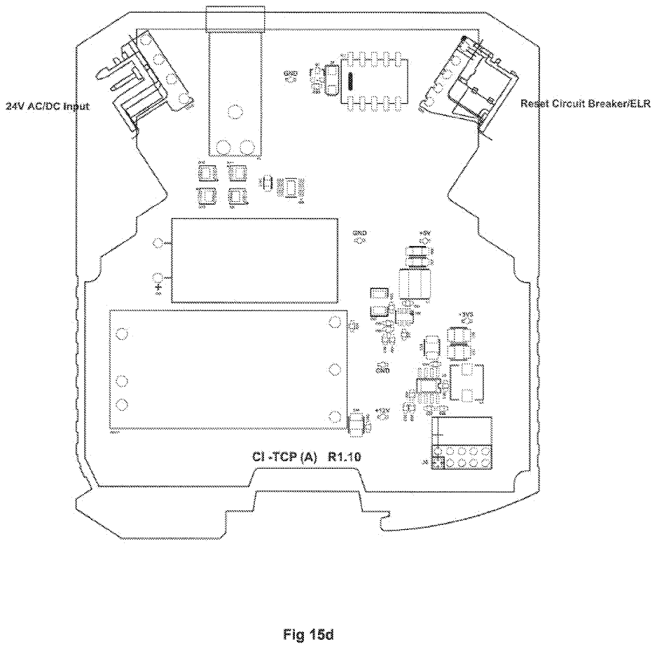

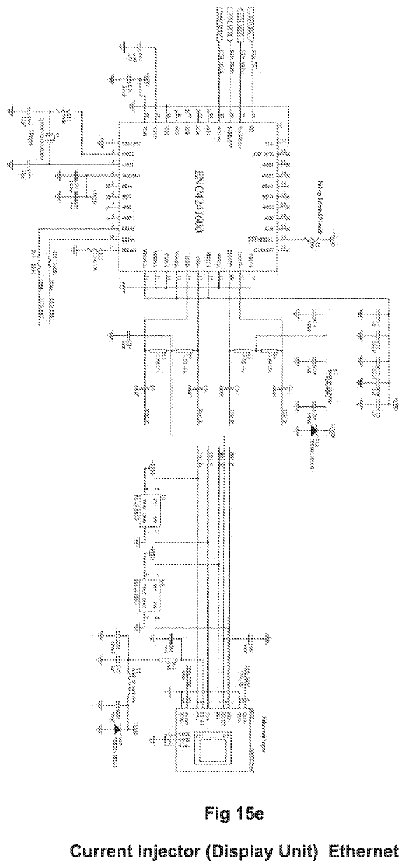

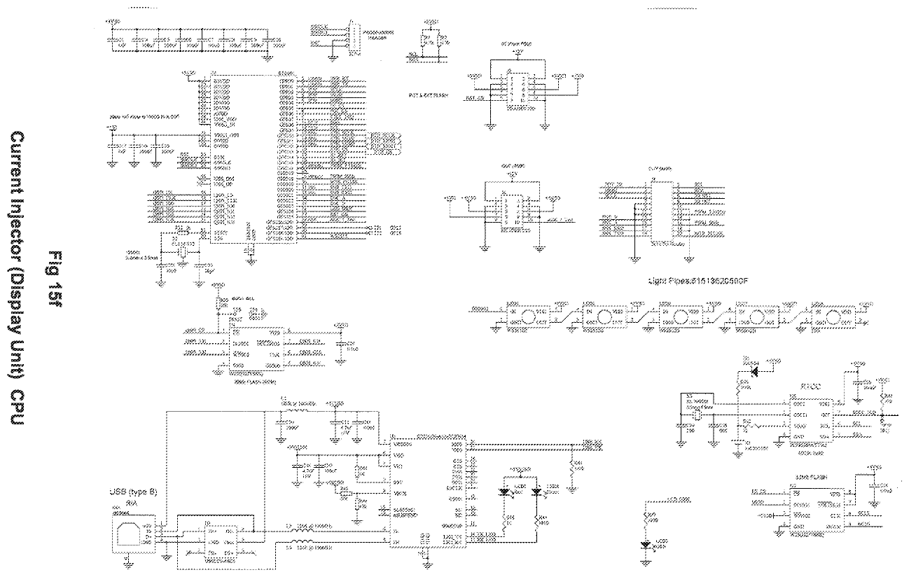

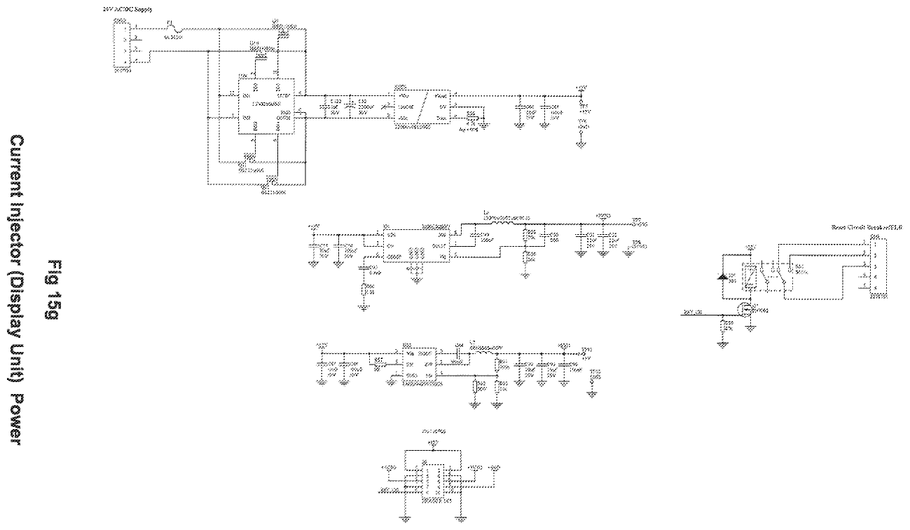

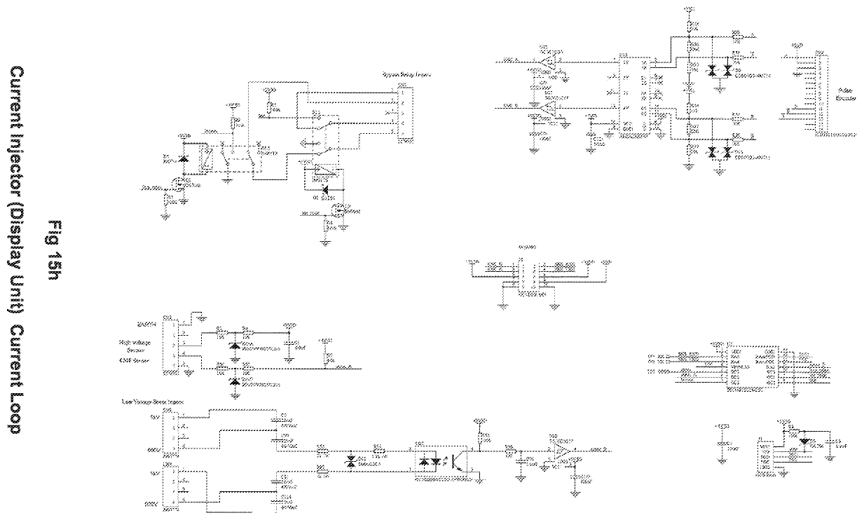

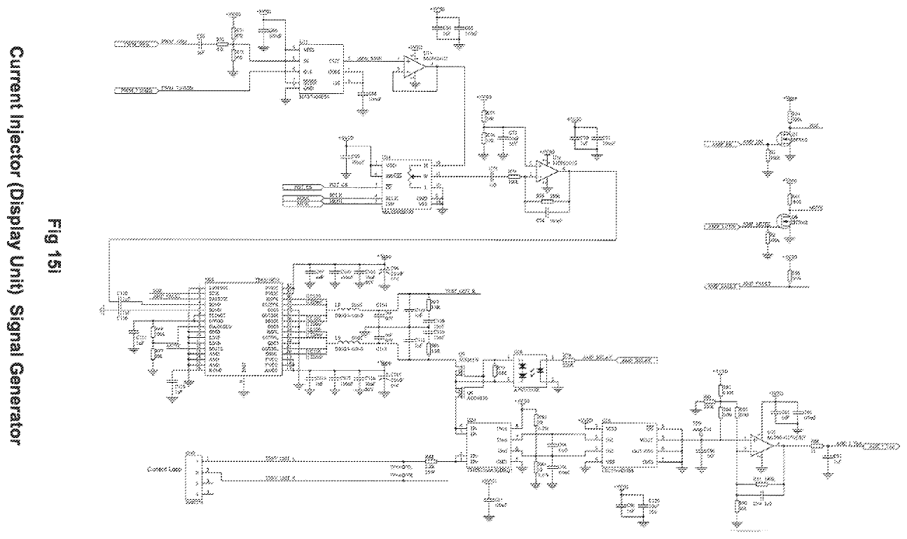

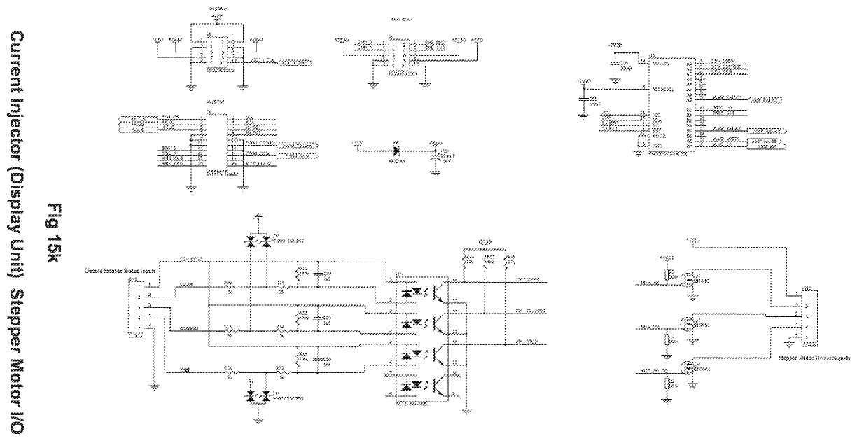

In a particular arrangement of the earth leakage test systems 10 and 12 in accordance with the present embodiments comprises at least the following equipment. FIGS. 14a to 14j are electric circuit diagrams of the portable units 16 and the interface unit 14 in accordance with the first embodiment of the invention; and FIGS. 15a to 15k are electric circuit diagrams of the remote test unit 27 in accordance with the third embodiment of the invention.

In the earth leakage test system 10 in accordance with the first embodiment of the invention, the portable test unit 16 comprise a hard case housing incorporating a display sunlight readable TFT display with touchscreen as well as a display keypad permitting to enter site information. The display shows set current, test ready indication start/stop test, and display of measured trip current and the time. The current (0 to >2A 50 Hz AC) is programable from the front panel. The trip time is measured in 1 ms increments.

The portable test unit 16 comprises an internal real-time clock (RTC) to timestamp the logged information. The logged information comprises: site information, date and time, trip current and the time for the relay to trip.

An internal battery Li-Ion with build-in charger is provided in the portable test unit 16. The external power supply is between 10 to 32 V and extra low voltages are used. In this respect, the operators are not exposed to any electrical hazard.

The voltage measurement interface occurs from the interface module 14. The interconnection between the portable test unit and the interface module 14 is via a multicore cable with ⅚ pin plug.

The interface module 14 comprises the following characteristics: 0-1000 VAC voltage sensing; Electromagnetic Field sensor (EMF) for 1000VAC or above; current loop and relay output.

The remote test unit 26 comprises the following characteristics: programable current 0-<2A 50 Hz AC; the trip time is measured in 1 ms increments; the voltage measurement interface occurs from the interface module 14; the connection to the industrial network is via ethernet connection using addressable registers; and, the external power supply is between 10 to 32 V (with a battery back-up) and extra low voltages are used-in this respect, the operators are not exposed to any electrical hazard.

There are provided in the remote test unit 26 an internal real-time clock (RTC) to timestamp the logged information. The logged information comprises: site information, date and time, trip current and the time for the relay to trip.

The reset unit 30 comprises the following characteristics: an external power supply of 10 to 32 V and configured to be unintrusive to switchgear operation. The reset unit 30 comprises a servo-drive for signal adjustment, custom brackets to suit switchgear of the universal fitment type.

The Integrated Current Injector has the following key points of difference from currently known available products.
Extra low voltage
No direct contact with electrical parts
Voltage independent
Used with toroidal coil type earth leakage relays
Quick connection to device under test
No need to access/open electrical equipment
Accurate timing and current functions
Reporting functions
Light weight
Cost effective
Reduced operational man hours
Remote operation (Model dependent)

Modifications and variations as would be apparent to a skilled addressee are deemed to be within the scope of the present invention.

For example, the system 10 and 12 and apparatus for testing has been described and depicted in the drawings in connection with a switchboard 11 comprising a single relay 23. However, the testing systems 10 and 12 and apparatus may be configured for testing a plurality of relays 23 by a person skilled in the art without undue burden. In this respect, the person skilled in the art could configure the systems 10 and 12 and apparatus for testing of a plurality of relays 13 without prolonged research, inventive experimentation or discovery, or tests that go beyond routine trial and error.

Further, it should be appreciated that the scope of the invention is not limited to the scope of the embodiments disclosed. These embodiments are intended for the purpose of exemplification only. Functionally equivalent products, formulations and methods are clearly within the scope of the invention as described herein.

Reference to positional descriptions, such as lower and upper, or inner and outer, are to be taken in context of the embodiments depicted in the figures, and are not to be taken as limiting the invention to the literal interpretation of the term but rather as would be understood by the skilled addressee.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprise”, “comprises,” “comprising,” “including,” and “having,” or variations thereof are inclusive and therefore specify the presence of stated features, integers, steps, operations, elements, and/or components, but do not preclude the presence or addition of one or more other features, integers, steps, operations, elements, components, and/or groups thereof.

Although terms such as first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Throughout this specification, unless the context requires otherwise, the word “comprise” or variations such as “comprises” or “comprising”, will be understood to imply the inclusion of a stated integer or group of integers but not the exclusion of any other integer or group of integers.

1. A testing apparatus for testing at least one relay of an electric circuit of a switchboard connected to a medium to high voltage mains power supply through a multi-phase circuit breaker for selective delivery of a first electric current to an end user power supply, the apparatus comprising a testing device being adapted to be operatively connected to the relay for tripping of the relay via a second current, wherein the second current is generated by a power supply other than the mains power supply.

2. A testing apparatus for testing at least one relay of an electric circuit of a switchboard connected to a medium to high voltage mains power supply through a multi-phase circuit breaker for selective delivery of a first electric current to an end user power supply, the apparatus comprising a testing device being adapted to be operatively connected to the relay for tripping of the relay via a low voltage second current, wherein the second current is generated by a power supply other than the mains power supply.

3. A testing apparatus according to claim 2, further comprising a current loop operatively connecting the testing apparatus to the relay for delivery of the second current to the relay for tripping thereof.

4. A testing apparatus according to claim 2, wherein the relay comprises an earth leakage relay adapted to sense imbalances of the first current delivered by the power mains supply.

5. A testing apparatus according to claim 4, wherein the current loop operatively engages the earth leakage relay for tripping of the earth leakage relay when the second current flows through the current loop.

6. A testing apparatus according to claim 5, wherein the earth leakage relay comprises a toroid for receiving the current loop for operatively engaging the earth leakage relay with the current loop for tripping of the earth leakage relay when the second current flows through the current loop.

7. A testing apparatus according to claim 2, further comprising a bypass circuit operatively connecting the relay with a shunt coil, the shunt coil being operatively connected to the circuit breaker for actuating the circuit breaker to an open condition when the relay has been tripped generating a tripping signal, the bypass circuit comprising a bypass switch for selectively impeding or allowing the tripping signal to actuate the circuit breaker to the open condition.

8. A testing apparatus according to claim 2, further comprising processing units configured for generating the second electric current to be delivered to the relay for testing purposes.

9. A testing apparatus according to claim 8, wherein the processing units further comprise the input/output means for setting-up the testing process by an operator and for identification of the switchboard including the relay, and collection of information representative of the testing process and of the switchboard and relay.

10. (canceled)

11. (canceled)

12. A testing apparatus according to claim 9, wherein the testing device comprises an interface module and a test unit operatively attached with respect to each other, the test unit generating the second current.

13. A testing apparatus according to 12, wherein the interface module is adapted to receive the second current for delivery to the current loop for tripping the relay.

14. A testing apparatus according to claim 12, wherein the interface module comprises the bypass switch.

15. A testing apparatus according to claim 12, wherein the interface module is installed within the switchboard.

16. A testing apparatus according to claim 12 wherein the interface module is incorporated in the test unit.

17. (canceled)

18. A testing apparatus according to claim 12, wherein the test unit is adapted for setting up the testing process and obtaining information about the testing procedure and status of the electric circuit including the relay.

19. (canceled)

20. A testing apparatus according to claim 12, wherein the test unit comprises a portable test unit for an operator to take to site for conducting the earth leakage testing while the operator is adjacent the switchboard.

21. A testing apparatus according to claim 12, wherein the test unit is adapted to be operated from a remote location such as a control room permitting setting up the testing procedure and obtaining, at the remote location, information about the testing procedure and status of the electric circuit of the switchboard including the relay, and information representative of the testing procedure and of the switchboard and relay comprising trip time, location of the switchboard, type of relay and status, and voltage.

22. A testing apparatus according to claim 2, further comprising a reset unit for resetting remotely the circuit breaker and/or the relay.

23. A testing apparatus according to claim 2, wherein the testing apparatus is adapted to be operatively connected via a multi-phase circuit breaker to a medium to high voltage mains power supply.

24. (canceled)

25. (canceled)

26. A system for testing at least one relay of an electric circuit of a switchboard connected to a medium to high voltage mains power supply through a circuit breaker for selective delivery of a first electric current to an end user power supply, wherein each multi-phase circuit breaker is connected to a mains power supply for selectively delivery of electric current to an end user power supply, the system comprising the electric circuit of the switchboard including the relay, and a testing apparatus according to claim 2.

27. (canceled)

28. A switchboard comprising a testing apparatus according to claim 2.

29. A method for testing least at one relay of an electric circuit of a switchboard connected to a mains power supply generating a first electric current through a circuit breaker for selective delivery of the first electric current to an end user power supply, the method comprises the steps of:
connecting an apparatus according to claim 2, to the electric circuit such that testing device is operatively connected to the relay for tripping of the relay via a second current delivered to the relay, wherein the second current is generated by a power supply other than the mains power supply;
generating the second current; and
forwarding the second current to the relay for tripping thereof.

30. (canceled)

31. (canceled)

32. A method according to claim 29, further comprising collecting information about the testing procedure and status of the electric circuit of the switchboard including the relay, and information representative of the testing process and of the switchboard and relay comprising trip time, location of the switchboard, type of relay and status, and voltage.
